(19) United States
(12) Patent Application Publication
(10) Pub. No.: US 2016/0035961 A1
(43) Pub. Date: Feb. 4, 2016

(54) DIELECTRIC ELEMENT AND PIEZOELECTRIC ELEMENT

(71) Applicant: Panasonic Corporation, Osaka (JP)

(72) Inventors: TOSHINARI NODA, Osaka (JP); HISAO SUZUKI, Aichi (JP); NAOKI WAKIYA, Tokyo (JP); NAONORI SAKAMOTO, Shizuoka (JP)

(21) Appl. No.: 14/733,556

(22) Filed: Jun. 8, 2015

(30) Foreign Application Priority Data
Jun. 11, 2014 (JP) 2014-120821

(51) Int. Cl. H01L 41/047; H01L 41/18

(52) U.S. Cl. CPC H01L 41/047; H01L 41/18

(57) ABSTRACT

A dielectric element includes a substrate, a first electrode layer on this substrate, a dielectric layer on the first electrode layer, and a second electrode layer on the dielectric layer. The first electrode layer contains lanthanum nickelate. The dielectric layer contains lead magnesate niobate-titanate represented by (1−x)Pb(Mg_{1/3}Nb_{2/3})O₃-xPbTiO₃, where x satisfies 0.28≦x≦0.33. The (100) plane of lead magnesate niobate-titanate is preferentially oriented along the interface between the first electrode layer and the dielectric layer.

### BACKGROUND

1. Technical Field

The technical field relates to a dielectric element and a piezoelectric element, particularly to those including a dielectric layer containing lead magnesate niobate-titanate.

2. Background Art

An oxide ferroelectric substance with a perovskite structure has superior ferroelectricity, piezoelectricity, pyroelectricity, and electro-optical characteristics. Hence, the substance is an effective material for a wide range of devices such as sensors, actuators, and memories, and thus is supposed to further expand its application range in the future.

In recent years, relaxor-type ferroelectric substances have been receiving attention. The substances have a high dielectric constant and a high piezoelectric constant. One of them is lead magnesate niobate-titanate (hereinafter, may be referred to as PMN-PT) that is a solid solution of lead magnesate niobate (PMN) and lead titanate (PT).

A monocrystal and a polycrystal of PMN-PT are known to present a high piezoelectric constant and a high dielectric constant. Especially in a composition of 0.65PMN-0.35PT, the relative dielectric constant is known to present a value as high as ∈ᵣ≧6,000 (refer to Appl. Phys. Lett. 80 (2002) P.4205).

### SUMMARY

The disclosure provides a dielectric element and a piezoelectric element that include a dielectric layer containing lead magnesate niobate-titanate with a high dielectric constant.

A dielectric element according to one aspect of the disclosure includes a substrate, a first electrode layer, a dielectric layer, and a second electrode layer. The first electrode layer is disposed on the substrate; the dielectric layer is disposed on the first electrode layer; and the second electrode layer is disposed on the dielectric layer. The first electrode layer contains lanthanum nickelate. The dielectric layer contains lead magnesate niobate-titanate represented by (1-x)Pb(Mg_{1/3}Nb_{2/3})O₃-xPbTiO₃, where x satisfies 0.28≦x≦0.33. The (100) plane of lead magnesate niobate-titanate is preferentially oriented along the interface between the first electrode layer and the dielectric layer.

A piezoelectric element according to one aspect of the disclosure has the same structure as the above-described dielectric element.

The disclosure allows producing a dielectric element and a piezoelectric element that include a dielectric layer containing lead magnesate niobate-titanate and having a high dielectric constant.

### BRIEF DESCRIPTION OF DRAWINGS

FIG. 1 is a sectional view of an example of a dielectric element according to an exemplary embodiment of the disclosure.

FIG. 2 is a sectional view of a first modified example of the dielectric element according to the exemplary embodiment of the disclosure.

FIG. 3 is a sectional view of a second modified example of the dielectric element according to the exemplary embodiment of the disclosure.

FIG. 4 is a sectional view of a third modified example of the dielectric element according to the exemplary embodiment of the disclosure.

FIG. 5 is a sectional view of a fourth modified example of the dielectric element according to the exemplary embodiment of the disclosure.

FIG. 6 is an observed image by an atomic force microscope of a cross section of a first electrode layer of the dielectric element according to the exemplary embodiment of the disclosure, the cross section being parallel to the interface between the first electrode layer and a dielectric layer.

FIG. 7 is an observed image by a scanning electron microscope of a cross section of the dielectric element according to the exemplary embodiment of the disclosure.

FIG. 8 is a graph showing an X-ray diffraction strength curve of the dielectric layer in the dielectric element according to the exemplary embodiment of the disclosure.

FIG. 9 is a graph showing a theoretically led X-ray diffraction strength of PMN-PT having a morphotropic phase boundary (MPB) composition.

FIG. 10 is a graph showing changes in the relative dielectric constant and the piezoelectric constant, with respect to the compositional change of PMN-PT, of the dielectric layer in the dielectric element according to the exemplary embodiment of the disclosure.

### DETAILED DESCRIPTION OF PREFERRED EMBODIMENT

Prior to the description of an exemplary embodiment of the disclosure, a brief description is made of disadvantages in conventional dielectric elements. To produce a dielectric element having a dielectric layer made of PMN-PT, when PMN-PT is formed into a thin film on an electrode, it is known that the dielectric constant, as well as the piezoelectric constant, of PMN-PT is degraded. Accordingly, it is almost impossible to increase the dielectric constant of a dielectric layer containing PMN-PT in a dielectric element by a conventional method.

Hereinafter, a description is made of an exemplary embodiment of the disclosure with reference to the drawings.

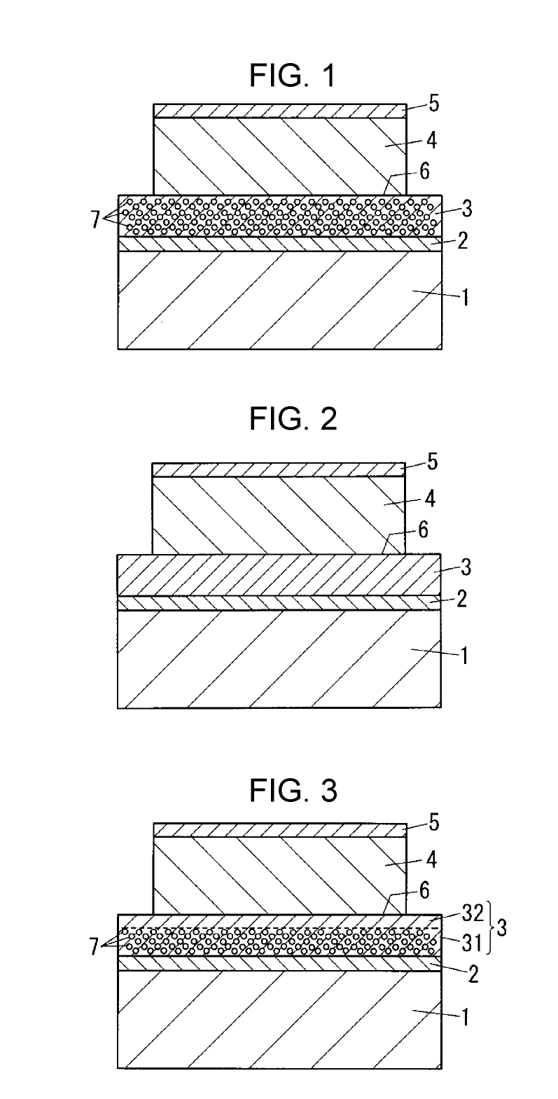

FIG. 1 is a sectional view of an example dielectric element according to the embodiment. This dielectric element includes substrate 1, first electrode layer 3 disposed on substrate 1, dielectric layer 4 disposed on first electrode layer 3, and second electrode layer 5 disposed on dielectric layer 4. In other words, substrate 1, first electrode layer 3, dielectric layer 4, and second electrode layer 5 are laminated in this order. First electrode layer 3 contains lanthanum nickelate (LaNiO₃). Hereinafter, lanthanum nickelate may be referred to as LNO. Dielectric layer 4 contains lead magnesate niobate-titanate represented by (1−x)Pb(Mg_{1/3}Nb_{2/3})O₃-xPbTiO₃. Hereinafter, the substance may be referred to as (1−x)PMN-xPT. The value x in the expression satisfies 0.28≦x≦0.33. The (100) plane of (1−x)PMN-xPT is preferentially oriented along interface 6 between first electrode layer 3 and dielectric layer 4.

In this embodiment, (1−x)PMN-xPT has a composition of the morphotropic phase boundary (MPB) between rhombohedral and tetragonal crystals, or a composition close to MPB. However, the crystal plane (e.g., (100) plane) of (1−x)PMN-xPT used in this embodiment is defined with the crystal system of (1−x)PMN-xPT regarded as a cubic system.

The above-described preferred orientation means that the (100) plane of (1−x)PMN-xPT is parallel to interface 6 more frequently than a case where the crystal planes of (1−x)PMN-xPT are randomly disposed. Preferred orientation is determined on the basis of the ratio of the strength of peaks assigned to the (100) plane, with respect to those assigned to planes not parallel with the (100) plane of (1-x)PMN-xPT in an X-ray diffraction strength curve obtained in X-ray diffraction measurement. If the ratio is larger than a case where crystal planes are randomly oriented, it is regarded as preferred orientation.

In this embodiment, as the (100) plane of (1−x)PMN-xPT is preferentially oriented along interface 6, a dielectric constant and a piezoelectric constant d₃₃ are high in the thicknesswise direction (i.e., the normal-line direction of interface 6) of dielectric layer 4.

According to the above-mentioned nonpatent literature, the dielectric constant of (1−x)PMN-xPT is maximal for x near 0.35. In this embodiment, however, the dielectric constant of PMN-xPT is not maximal for x near 0.35; higher when x satisfies 0.28≦x≦0.33 than when x is near 0.35. Further, when x satisfies 0.28≦x≦0.33, the piezoelectric constant d₃₃ becomes higher. This is supposedly because of the following. That is, in this embodiment, when dielectric layer 4 containing (1−x)PMN-xPT is formed on first electrode layer 3 containing lanthanum nickelate, the MPB composition of (1−x)PMN-xPT in dielectric layer 4 shifts closer to the PMN-rich side than usual.

Hence, the dielectric element of this embodiment includes dielectric layer 4 containing (1−x)PMN-xPT and having a high dielectric constant and a high piezoelectric constant d₃₃.

Meanwhile, it is preferable that dielectric layer 4 has a compressive stress along interface 6 between first electrode layer 3 and dielectric layer 4, which further increases the dielectric constant and piezoelectric constant d₃₃ of dielectric layer 4. Note that the presence or absence of a compressive stress in dielectric layer 4 and its value are evaluated by X-ray residual stress measurement (sin²Ψ method).

Furthermore, it is preferable that dielectric layer 4 has a thermal expansion coefficient smaller than that of first electrode layer 3, which easily causes a compressive stress in dielectric layer 4 formed on first electrode layer 3.

Furthermore, it is preferable that first electrode layer 3 contains multiple pores 7 therein. Thanks to pores 7, binding of dielectric layer 4 by substrate 1 is suppressed, thereby the extension or contraction of dielectric layer 4 is hard to be restricted by substrate 1. Therefore, a decrease of the dielectric constant and piezoelectric constant d₃₃ of dielectric layer 4 is suppressed. Note that the volume ratio of pores 7 in first electrode layer 3 preferably falls in the range from 10% to 50%, where the volume ratio is represented by the occupancy of pores 7 by cross-sectional observation of first electrode layer 3.

In a case that first electrode layer 3 contains multiple pores 7, it is as well preferable that the diameters of pores 7 decreases from substrate 1 toward dielectric layer 4. This case as well suppresses binding of dielectric layer 4 by substrate 1 more effectively, and a compressive stress can be generated in dielectric layer 4 more easily.

Furthermore, it is preferable that the dielectric element according to the embodiment has diffusion prevention layer 2 between substrate 1 and first electrode layer 3. In this case, mutual diffusion of materials of first electrode layer 3 and substrate 1 can be suppressed.

Moreover, it is preferable that the (100) plane of LNO is preferentially oriented along interface 6 between first electrode layer 3 and dielectric layer 4 In this case, the (100) plane of (1−x)PMN-xPT in dielectric layer 4 becomes preferentially oriented along interface 6 more easily.

Meanwhile, LNO has a perovskite structure distorted in a rhombohedral; however, the crystal plane (e.g., (100) plane) of the LNO is defined with the crystal system of the LNO regarded as a cubic system. The above-described preferred orientation means that the (100) plane of the LNO is parallel to interface 6 more frequently than a case where the crystal planes of the LNO are randomly disposed, similarly to the case of (1−x)PMN-xPT.

Hereinafter, a more detailed description is made of a dielectric element according to the embodiment.

Substrate 1 is formed of semiconductor monocrystalline, metallic, glass-based, or ceramic materials, for example. A semiconductor monocrystalline material is represented by silicon. A metallic material includes stainless-steel, titanium, aluminum, and magnesium. A glass-based material includes quartz glass and borosilicate glass. A ceramic material includes alumina and zirconia. The material of substrate 1 is not limited to these materials. In this embodiment, substrate 1 favorably has a small thermal expansion coefficient, and thus substrate 1 is favorably made of silicon or quartz glass.

In the example shown in FIG. 1, the dielectric element has diffusion prevention layer 2. Diffusion prevention layer 2 is capable of suppressing mutual diffusion between the constituent materials of substrate 1 and first electrode layer 3. It is preferably that diffusion prevention layer 2 is formed of an amorphous oxide material free from crystal grain boundaries, such as amorphous silicon dioxide.

Note that the dielectric element does not necessarily need to have diffusion prevention layer 2. For example, when first electrode layer 3 is formed on substrate 1 in a relatively low-temperature condition, mutual diffusion is suppressed without diffusion prevention layer 2. Accordingly, the dielectric element does not need diffusion prevention layer 2, and substrate 1 and first electrode layer 3 may directly contact with each other.

First electrode layer 3 contains LNO. LNO has a space group of R-3c (“-3” is a symbol that has a bar over “3”) and has a perovskite structure distorted in a rhombohedral. The rhombohedral system is in the form of a₀=5.461 Å (a₀=aₚ), and α=60°; the pseudo-cubic system is in the form of a₀=3.84 Å. The resistivity of LNO is 1×10⁻³ (Ω·cm, 300K). That is, LNO is an oxide having metallic electricity conductivity and does not change to an electric insulator due to temperature change. As described above, it is preferable that the (100) plane of LNO in first electrode layer 3 is preferentially oriented along interface 6 between first electrode layer 3 and dielectric layer 4. In this case, the (100) plane of (1−x)PMN-xPT in dielectric layer 4 on first electrode layer 3 becomes preferentially oriented along interface 6 more easily.

The extent of orientation of the (100) plane of LNO can be evaluated by the degree of orientation. The degree (β(100)) of orientation of the (100) plane of LNO is defined by the next expression.

β(100)=J(100)/ΣJ(hkl)

ΣJ(hkl) is a total of the strengths of all peaks that appear in the range of 2θ from 10° to 70° in an X-ray diffraction strength curve obtained by X-ray diffraction measurement of LNO using Cu-Kα rays. The value of J(100) is a total of the strengths of peaks assigned to the (100) plane that appear in the X-ray diffraction strength curve and the strengths of peaks assigned to planes parallel to the (100) plane. In this embodiment, β(100) favorably falls within the range from 0.5 to 1, inclusive. In this case, the (100) plane of (1−x)PMN-xPT in dielectric layer 4 becomes preferentially oriented along interface 6 more easily. The value of β(100) within the range from 0.95 to 1, inclusive, is particularly preferable.

First electrode layer 3 can contain only LNO. Alternatively, first electrode layer 3 may contain LNO as the principal component. Thus, first electrode layer 3 may contain a solid solution of LNO as the principal component and a perovskite metal oxide other than LNO. Examples of a perovskite metal oxide other than LNO include a metal oxide that has a composition in which nickel atoms of LNO are replaced with metal atoms other than nickel atoms, such as LaFeO₃, LaAlO₃, LaMnO₃, and LaCoO₃, concretely. Thus, first electrode layer 3 can contain one or more materials chosen from the group consisting of LaNiO₃—LaFeO₃-based material (a solid solution of LNO and LaFeO₃), LaNiO₃—LaAlO₃-based material (a solid solution of LNO and LaAlO₃), LaNiO₃—LaMnO₃-based material (a solid solution of LNO and LaMnO₃), and LaNiO₃—LaCoO₃-based material (a solid solution of LNO and LaCoO₃).

It is preferable that first electrode layer 3 contains pores 7 therein, which suppresses binding of dielectric layer 4 by substrate 1, thereby the extension or contraction of dielectric layer 4 is hard to be restricted by substrate 1. This prevents the piezoelectric constant d₃₃ of dielectric layer 4 from decreasing.

A more detailed description is made of effects of pores 7 in first electrode layer 3. In a case that dielectric layer 4 is formed on substrate 1, substrate 1 restricts extension or contraction of dielectric layer 4 when a force is exerted on dielectric layer 4 or an electric field is applied to dielectric layer 4. The thinner dielectric layer 4 is, the more prominent this restriction is. Such restriction lowers the piezoelectric constant (effective piezoelectric constant) of dielectric layer 4.

Under the circumstances, first electrode layer 3 containing multiple pores 7 therein gives flexibility to first electrode layer 3. Flexibility of first electrode layer 3 interposed between substrate 1 and dielectric layer 4 discourages substrate 1 from restricting the extension and contraction of dielectric layer 4. Therefore, dielectric layer 4 is hard to be restrained by substrate 1. This prevents the piezoelectric constant of dielectric layer 4 from degrading.

Note that the effective piezoelectric constant of dielectric layer 4 when dielectric layer 4 is restrained by substrate 1 is evaluated by the next expression.

$${d}_{33}^{eff} = {d}_{33} - {d}_{31} [ \frac{( {v}_{sub} / {Y}_{sub} ) + {s}_{13}^{E}}{{s}_{11}^{E} + {s}_{12}^{E}} ]$$

The constant d₃₃^{eff} is the effective piezoelectric constant of dielectric layer 4 when restrained by substrate 1. The constants d₃₃ and d₃₁ are piezoelectric constants of dielectric layer 4 when not restrained by substrate 1. The constants s₁₁^{E}, s₁₂^{E}, and s₁₃^{E} are elastic compliance of dielectric layer 4 in a constant electric field. The constant Y_{sub} is the Young's modulus of substrate 1. The constant v_{sub} is the Poisson's ratio of substrate 1.

Here, assumption is made that substrate 1 made of silicon has dielectric layer 4 made of (1−x)PMN-xPT thereon. Parameters are assumed to be d₃₃=2,820 pm/V, d₃₁=−1,330 pm/V, s₁₁^{E}=69 pm²/N, s₁₂^{E}=−11 pm²/N, s₁₃^{E}=−56 pm²/N, Y_{sub}=179 GPa, and v_{sub}=0.22. Then, the above expression determines that an effective piezoelectric constant d₃₃^{eff} is 300 pm/V, which is one digit smaller than the original piezoelectric constant d₃₃. In this embodiment, pores 7 prevent the piezoelectric constant from degrading due to restraint by substrate 1.

If first electrode layer 3 contains pores 7 therein, it is as well preferable that the diameter of pores 7 decreases from substrate 1 toward dielectric layer 4, which further increases the dielectric constant and the piezoelectric constant of dielectric layer 4. This is supposedly because of the following. That is, pores 7 with a smaller diameter near interface 6 between dielectric layer 4 and first electrode layer 3 increases the crystallinity of first electrode layer 3 near interface 6. Accordingly, the crystallinity of dielectric layer 4 increases. In addition, the presence of pores 7 may cause the constituent materials of dielectric layer 4 to diffuse to pores 7; however, the smaller diameter of pores 7 near interface 6 prevents such diffusion. Such distribution of pores 7 with different diameters suppresses the strength degradation of dielectric layer 4 due to pores 7. This prevents the mechanical strength degradation of the whole dielectric element, thereby increasing the reliability of the dielectric element.

However, as shown in FIG. 2, it is not essential that first electrode layer 3 contains multiple pores 7. FIG. 2 is a sectional view of a first modified example of a dielectric element according to the embodiment. In other words, first electrode layer 3 may have a closely packed structure without containing pores therein. The absence of pores in first electrode layer 3 increases the crystallinity of first electrode layer 3, and supposedly increases that of dielectric layer 4 accordingly. Consequently, the dielectric constant and piezoelectric constant d₃₃ of dielectric layer 4 are further increased. Besides, the absence of pores in first electrode layer 3 supposedly suppresses the diffusion of the constituent materials from dielectric layer 4 to first electrode layer 3. Also, this prevents the strength degradation of first electrode layer 3 due to pores, and thus prevents the mechanical strength degradation of the whole dielectric element, thereby increasing the reliability of the dielectric element.

As shown in FIG. 3, first electrode layer 3 may have first layer 31 and second layer 32 that is interposed between first layer 31 and dielectric layer 4. FIG. 3 is a sectional view of a second modified example of the dielectric element according to the embodiment. It is preferable that first layer 31 contains pores 7 therein and second layer 32 does not contain pores 7 therein. In this case, the absence of pores 7 near interface 6 between dielectric layer 4 and first electrode layer 3 increases the crystallinity of first electrode layer 3 near interface 6, and supposedly increases that of dielectric layer 4 accordingly. Consequently, the dielectric constant and piezoelectric constant d₃₃ of dielectric layer 4 are further increased. In addition, the absence of pores 7 near interface 6 supposedly suppresses the diffusion of the constituent materials from dielectric layer 4 to pores 7. Also, first layer 31 thus containing pores 7 and second layer 32 not containing pore 7 suppress the strength degradation of first electrode layer 3 due to pores 7. This prevents the mechanical strength degradation of the whole dielectric element, thereby increasing the reliability of the dielectric element.

First electrode layer 3 may include a layer not containing LNO as the principal component. In other words, first electrode layer 3 may include both a layer containing LNO as the principal component and a layer not containing LNO as the principal component. For example, as shown in FIG. 3, if first electrode layer 3 has first layer 31 and second layer 32, it is allowed that first layer 31 contains LNO and second layer 32 does not contain LNO. Of course, both first layer 31 and second layer 32 may contain LNO.

If second layer 32 does not contain LNO, it is preferable that second layer 32 contains a perovskite conductive metal oxide other than LNO. Concrete examples of such a perovskite conductive metal oxide include strontium ruthenate, lanthanum-strontium-cobalt oxide, and lanthanum-strontium-manganese oxide.

If second layer 32 does not contain LNO as well, it is preferable that the (100) plane of a conductive metal oxide contained in second layer 32 is preferentially oriented along interface 6 between first electrode layer 3 and dielectric layer 4. In this case, the (100) plane of (1−x)PMN-xPT in dielectric layer 4 becomes preferentially oriented more easily.

Dielectric layer 4 contains (1−x)PMN-xPT and x satisfies 0.28≦x≦0.33 as described above. Further, the (100) plane of (1−x)PMN-xPT is preferentially oriented along interface 6 between first electrode layer 3 and dielectric layer 4.

The extent of orientation of the (100) plane of (1−x)PMN-xPT can be evaluated by the degree of orientation. The degree of orientation (α(100)) of the (100) plane of (1−x)PMN-xPT is defined by the next expression.

α(100)=I(100)/ΣI(hkl)

ΣI(hkl) is a total of the strengths of all peaks that appear in the range of 2θ from 10° to 70° in an X-ray diffraction strength curve obtained by X-ray diffraction measurement of (1−x)PMN-xPT using Cu-Kα rays. The value of I(100) is a total of the strengths of peaks assigned to the (100) plane and the strengths of peaks assigned to planes parallel to the (100) plane both of which appear in the X-ray diffraction strength curve. It is preferable that the value of α(100) falls within the range from 0.5 and to 1, inclusive. In this case, a high dielectric constant and a high piezoelectric constant d₃₃ of dielectric layer 4 can be achieved. The degree of orientation in the range from 0.95 to 1, inclusive, is particularly preferable.

The thickness of first electrode layer 3 falls in the range from 20 nm to 550 nm for instance, but not limited to this range. In the case that first electrode layer 3 has first layer 31 and second layer 32, the thickness of first layer 31 falls in the range from 20 nm to 500 nm, for instance; second layer 32, from 20 nm to 200 nm, for instance, but not limited to the ranges.

Dielectric layer 4 can contain only (1−x)PMN-xPT. Dielectric layer 4 may contain (1−x)PMN-xPT as the principal component. Accordingly, dielectric layer 4 may contain (1−x)PMN-xPT as the principal component and a perovskite metal oxide other than (1−x)PMN-xPT. In this case, dielectric layer 4 may contain a solid solution of (1−x)PMN-xPT and a perovskite metal oxide other than (1−x)PMN-xPT. For a concrete example, it is allowed that dielectric layer 4 contains (1−x)PMN-xPT and further contains one or more perovskite metal oxides selected from the group consisting of Pb(Zn_{1/3}Nb_{2/3})O₃, PbTiO₃, and Pb(ZryTi1−y)O₃ (0<y<1). If dielectric layer 4 contains (1−x)PMN-xPT and a perovskite metal oxide other than (1−x)PMN-xPT, the content of (1−x)PMN-xPT is preferably 50 mol % or more in whole dielectric layer 4.

It is preferable that dielectric layer 4 has a compressive stress generated along interface 6 between first electrode layer 3 and dielectric layer 4. In this case, the MPB composition of (1−x)PMN-xPT supposedly shifts closer to the PMN-rich side than a case without a compressive stress. Accordingly, the dielectric constant and piezoelectric constant d₃₃ of dielectric layer 4 are increased. A compressive stress in dielectric layer 4 is measured in the central part of dielectric layer 4. The value of a compressive stress in dielectric layer 4 is preferably 200 MPa or more. In this case, the dielectric constant and piezoelectric constant d₃₃ of dielectric layer 4 are particularly increased. This respect is described later in reference to FIG. 10.

It is preferable that dielectric layer 4 contains polycrystals of a columnar crystal structure that has longer grain boundaries in the thickness direction of dielectric layer 4. In other words, it is preferable that dielectric layer 4 contains multiple columnar crystals and the long grain boundaries appear along the thickness direction of dielectric layer 4 in the cross section orthogonal to interface 6 of dielectric layer 4. The columnar crystal structure contains only (1−x)PMN-xPT, for example; alternatively, a solid solution of (1−x)PMN-xPT as the principal component and a perovskite metal oxide other than (1−x)PMN-xPT. Dielectric layer 4 thus containing a columnar crystal structure moderates a stress inside dielectric layer 4 even if dielectric layer 4 undergoes an external force, which suppresses cracking in dielectric layer 4.

The thickness of dielectric layer 4 falls in the range from 100 nm to 10,000 nm, but not limited to the range.

The absolute value of the difference between the lattice constant of a metal oxide in contact with dielectric layer 4 of first electrode layer 3; and the lattice constant of (1−x)PMN-xPT in dielectric layer 4 is preferably 10% or less of the lattice constant of (1−x)PMN-xPT. The metal oxide in contact with dielectric layer 4 of first electrode layer 3 refers to, if first electrode layer 3 contains only LNO, LNO; if first electrode layer 3 contains only a solid solution containing LNO, the solid solution; if first electrode layer 3 has first layer 31 and second layer 32, the metal oxide contained in second layer 32.

A small difference between the lattice constant of a metal oxide and that of (1−x)PMN-xPT described above provides favorable lattice matching between first electrode layer 3 and dielectric layer 4. Lattice matching refers to matching of lattice constants between unit lattices. The following phenomenon is generally known. That is, when a film is formed on a component, favorable lattice matching between the component and the film material causes the crystals composing the film to epitaxially grow, thereby easily aligning the crystal planes of the film with those of the component. If the lattice matching between first electrode layer 3 and dielectric layer 4 is favorable and the (100) plane of first electrode layer 3 is preferentially oriented along interface 6, the crystals composing dielectric layer 4 form epitaxial nuclei when dielectric layer 4 is formed on first electrode layer 3. Accordingly, the (100) plane of dielectric layer 4 also becomes preferentially oriented along interface 6 more easily, thereby particularly increasing the dielectric constant and piezoelectric constant d₃₃ of dielectric layer 4.

Typically, the lattice constant of monocrystals of PMN-PT near the MPB composition is approximately 4.02 Å; the pseudo cubic lattice constant of LNO is 3.84 Å. Accordingly, if first electrode layer 3 is made of LNO and dielectric layer 4 is made of PMN-PT, the lattice matching between first electrode layer 3 and dielectric layer 4 is greatly favorable. Thus, if the (100) plane of LNO is preferentially oriented along interface 6 between first electrode layer 3 and dielectric layer 4, the (100) plane of PMN-PT in dielectric layer 4 also becomes preferentially oriented along interface 6 particularly more easily. Therefore, the dielectric constant and piezoelectric constant d₃₃ of dielectric layer 4 are especially increased. Even if first electrode layer 3 contains a metal oxide other than LNO and dielectric layer 4 contains a metal oxide other than PMN-PT, the (100) plane of (1−x)PMN-xPT in dielectric layer 4 becomes preferentially oriented along interface 6 more easily if favorable lattice matching between the metal oxide in contact with dielectric layer 4 in first electrode layer 3 is established.

Lattice matching is favorable also in the following case. That is, first electrode layer 3 has first layer 31 and second layer 32; and second layer 32 contains at least a type of conductive metal oxide selected from the group consisting of strontium ruthenate, lanthanum-strontium-cobalt oxide, and lanthanum-strontium-manganese oxide. That is, the absolute value of the difference between the lattice constant of each of these conductive metal oxides and the lattice constant of (1−x)PMN-xPT is 10% or less of the lattice constant of (1−x)PMN-xPT. Accordingly, if second layer 32 contains at least a type of conductive metal oxide selected from the group consisting of strontium ruthenate, lanthanum-strontium-cobalt oxide, and lanthanum-strontium-manganese oxide; and the (100) plane of the conductive metal oxide is preferentially oriented along interface 6, the (100) plane of (1−x)PMN-xPT in dielectric layer 4 becomes preferentially oriented more easily.

Second electrode layer 5 is formed of a conductive material. Second electrode layer 5 is made of gold, for instance. The thickness of second electrode layer 5 falls in the range from 0.05 μm to 0.50 μm. Second electrode layer 5 is preferably produced by vapor deposition, where a stress hardly remains in second electrode layer 5. Second electrode layer 5 can be produced by various film-forming methods such as sputtering.

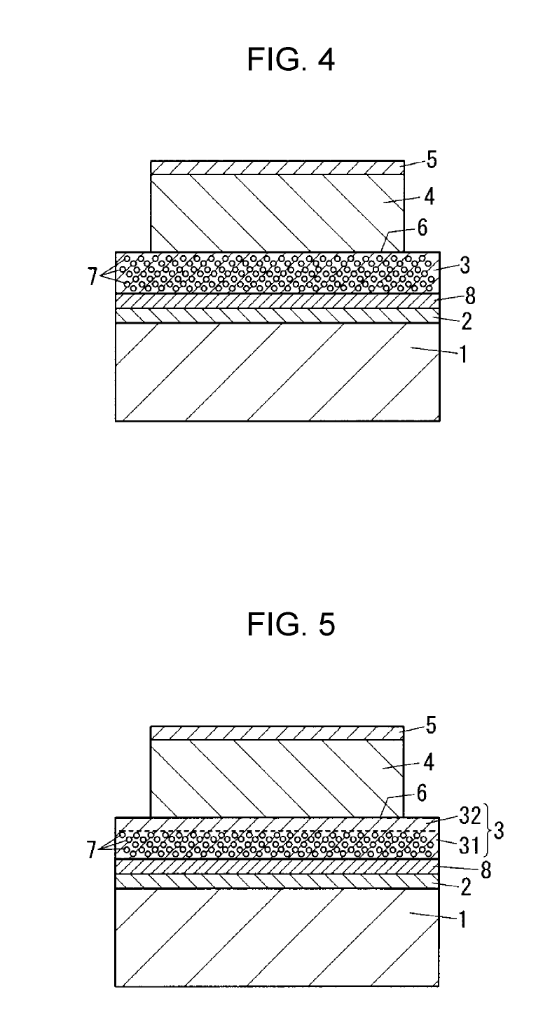

FIG. 4 is a sectional view of a third modified example of the dielectric element according to the embodiment. As shown in the figure, it is allowed that highly conductive layer 8 having an electric resistivity lower than that of first electrode layer 3 lies between first electrode layer 3 and substrate 1; and highly conductive layer 8 directly overlaps with first electrode layer 3. Highly conductive layer 8 is formed of a material such as a precious metal and a precious-metal oxide. For example, highly conductive layer 8 is formed of one or more types of materials selected from the group consisting of platinum, ruthenium, iridium, rhenium, ruthenium oxide, iridium oxide, and rhenium oxide. A dielectric element thus having highly conductive layer 8 apparently increases the conductivity of first electrode layer 3, thereby improving the performance of the dielectric element.

A dielectric element according to the embodiment, having a high dielectric constant and a high piezoelectric constant, is suitably used for various devices such as a capacitor, a piezoelectric sensor, a dielectric bolometer type infrared sensor, a piezoelectric actuator, and a ultrasonic motor. A piezoelectric element according to the embodiment has this dielectric element. A piezoelectric element utilizes the piezoelectricity of the dielectric element. The piezoelectric element is suitably used for devices such as a piezoelectric sensor, a piezoelectric actuator, and a ultrasonic motor.

The piezoelectric element is capable of outputting an electric signal based on the pressure of an external force applied to dielectric layer 4. The piezoelectric element can extend and contract in response to a voltage applied between first electrode layer 3 and second electrode layer 5, and produce displacement in the extending/contracting direction or an orthogonal direction thereto.

Note that the above-described dielectric element according to the embodiment is an example of the disclosure. Accordingly, the disclosure is not limited to the above-described embodiment, but clearly, various types of modifications may be added according to design requirements and other conditions within a scope that does not deviate from the technical concept of the present disclosure.

For example, a dielectric element may be structured as shown in FIG. 5. FIG. 5 is a sectional view of a fourth modified example of the dielectric element according to the embodiment.

This dielectric element includes both diffusion prevention layer 2 and highly conductive layer 8. Further, first electrode layer 3 includes first layer 31 containing multiple pores 7, and second layer 32 provided between first layer 31 and dielectric layer 4 and not containing pores 7. The dielectric element does not need to essentially have diffusion prevention layer 2 and highly conductive layer 8.

Substrate 1 is plate-shaped in this embodiment, but its shape is not limited to this. For example, substrate 1 may have a three-dimensional shape with more surfaces than a case where substrate 1 is plate-shaped. Furthermore, first electrode layer 3, dielectric layer 4, and second electrode layer 5 may be provided on each of the two or more surfaces of substrate 1. In this case, a device such as an actuator capable of multidirectional displacement can be achieved, for example.

Next, a description is made of a concrete example of producing a dielectric element according to the embodiment.

First, substrate 1 made of silicon is prepared. Heating the surface of substrate 1 for oxidization allows diffusion prevention layer 2 made of silicon oxide to be formed easily.

Next, a description is made of a procedure of producing first electrode layer 3. First electrode layer 3 is produced by chemical solution deposition. Concretely, a precursor solution containing an LNO precursor is prepared first. For example, lanthanum nitrate hexahydrate (La(NO₃)₃.6H₂O) and nickel acetate tetrahydrate (CH₃COO)₂Ni.4H₂O) are prepared as precursors. These precursors are dissolved in a solvent such as a mixed solvent of 2-methoxy ethanol and 2-aminoethanol for preparing a precursor solution.

The precursor solution is applied onto diffusion prevention layer by spin coating for instance for forming a precursor film. Subsequently, after the precursor film is heat-dried, the precursor in the precursor film is heat-decomposed for removing organic components and organic groups in the precursors from the precursor film. Note that all organic components and organic groups do not have to be removed from the precursor film, but it is adequate if most of them are removed. For example, the precursor film is heat-dried at 150° C. for 10 minutes, and then is heated at 350° C. for 10 minutes for heat-decomposing the precursor. After these procedures, an intermediate layer is formed. To produce first electrode layer 3 of a desired thickness, a process including forming a precursor film, heat-drying the precursor film, and heat-decomposing the precursor is repeated more than once for laminating multiple intermediate layers.

As a result that the intermediate layer thus formed is heat-annealed for crystallization, first electrode layer 3 made of LNO is formed. When the intermediate layer is heat-annealed, it is preferable that the intermediate layer first undergoes rapid temperature raising in a heating furnace for instance. Concretely, the intermediate layer is rapidly heated first at a temperature raising speed of 200° C./min to 700° C. for example, and subsequently the intermediate layer is heated at 700° C. for 5 minutes. The heating furnace is preferably a rapid thermal annealing furnace; however, it may be an electric furnace or a laser annealing apparatus.

If first electrode layer 3 is thus formed by chemical solution deposition, the (100) plane of LNO in first electrode layer 3 becomes preferentially oriented more easily along the surface (i.e., interface 6 between first electrode layer 3 and dielectric layer 4) opposite to substrate 1 in first electrode layer 3. Why the (100) plane is preferentially oriented is not clearly understood; however, first rapidly temperature-raising the intermediate layer in heat annealing supposedly contributes to the preferential orientation to a large degree. During the process of temperature-raising the intermediate layer, there is supposedly a certain temperature condition in which the (100) plane is not oriented along interface 6 and LNO is easily crystallized. Accordingly, if the temperature of the intermediate layer is slowly raised, crystallization occurs during temperature-raising, and crystals in which the (100) plane of which is not oriented along interface 6 are easily mixed in first electrode layer 3, which supposedly causes random crystal directions. On the other hand, if the intermediate layer is rapidly temperature-raised, crystallization is suppressed during temperature-raising, and the (100) plane of LNO supposedly becomes oriented along interface 6 more easily.

When first electrode layer 3 is formed, if the condition of applying the precursor solution is adjusted, pores 7 can be contained in first electrode layer 3 and the diameter of pores 7 can be controlled. A thicker precursor film supposedly discharges more organic matter when the precursor film is heated. In addition, a thick precursor film may discourage close packing of the film comparing to the case where a precursor film is thin. Accordingly, a larger thickness of the precursor film for example causes pores 7 to be contained in first electrode layer 3 more easily and the diameter of pores 7 to be increased. Conversely, a smaller thickness of the precursor film causes the diameter of pores 7 to be decreased. Controlling the thickness of the precursor film can even prevent pores 7 from being formed.

A solvent having a larger molecular weight in the precursor solution causes pores 7 to be contained in first electrode layer 3 more easily and the diameter of pores 7 to be increased. If the solvent is a mixed solvent of 2-methoxy ethanol and 2-aminoethanol for instance, first electrode layer 3 contains pores 7 particularly easily.

When two or more intermediate layers are laminated, if the thickness of the precursor film for the intermediate layer is decreased with the distance from substrate 1, first electrode layer 3 is more closely packed with the distance from substrate 1. Accordingly, the diameter of pores 7 in first electrode layer 3 can be controlled so as to be smaller with the distance from substrate 1. Instead, first electrode layer 3 can be formed to have first layer 31 containing pores 7 and second layer 32 not containing pores 7.

Note that the presence or absence of pores 7 and the diameters of pores 7 may be controlled by a manner other than adjusting the thickness of the precursor film. The distribution of diameters of pores 7 may be controlled by a manner such as adjusting the concentration of the precursor solution and changing the type of a solvent in the precursor solution, for example. If the solvent is an organic solvent of a small molecular weight, such as ethanol and acetic acid, or a mixture of an organic solvent of a small molecular weight and water, the film becomes closely packed more easily. According to the method, the diameters of pores 7 can be small or pores 7 can be eliminated.

When first electrode layer 3 containing LNO and a conductive metal oxide other than LNO is produced as well, the (100) planes of LNO and a conductive metal oxide other than LNO become preferentially oriented along interface 6 more easily if first electrode layer 3 is produced by chemical solution deposition.

When first layer 31 containing LNO is produced first and then second layer 32 not containing LNO is produced, first layer 31 is produced using a precursor solution containing a precursor of LNO by chemical solution deposition firstly. Subsequently, second layer 32 can be produced using a precursor solution containing a precursor of a conductive metal oxide other than LNO by chemical solution deposition. In this case, the (100) plane of LNO in first layer 31 becomes preferentially oriented along interface 6 more easily. Further, the (100) plane of the conductive metal oxide in second layer 32 formed on first layer 31 also becomes preferentially oriented along interface 6 more easily. This is supposedly because the crystals composing second layer 32 form epitaxial nuclei more easily when second layer 32 is formed.

For producing first electrode layer 3 by chemical solution deposition, a vacuum process required in vapor deposition such as sputtering is not needed. This allows first electrode layer 3 to be produced easily as well as at low costs. In this embodiment, the orientation direction of the (100) plane of LNO hardly depends on the material of substrate 1. Accordingly, the (100) plane of LNO in first electrode layer 3 becomes preferentially oriented along interface 6 more easily without being influenced by the material of substrate 1.

Note that first electrode layer 3 may be produced by various publicly known film-forming methods including vapor deposition such as sputtering method, and hydrothermal synthesis.

Next, a description is made of a procedure for producing dielectric layer 4. Dielectric layer 4 is as well produced by chemical solution deposition. Concretely, a precursor solution containing a precursor of (1−x)PMN-xPT is first prepared. Examples of a precursor include lead acetate (II) trihydrate (Pb(OCOCH₃)₂.3H₂O), magnesium ethoxide (Mg(OC₂H₅)₂), niobium (V) ethoxide (Nb(OC₂H₅)₅), and titanium isopropoxide (Ti(OCH(CH₃)₂)₄). These precursors are dissolved into a solvent such as ethanol for preparing a precursor solution.

The precursor solution is applied onto first electrode layer 3 by spin coating for instance for forming a precursor film. Subsequently, after the precursor film is heat-dried, the precursor in the precursor film is heat-decomposed for removing organic components and organic groups in the precursor from the precursor film. All organic components and organic groups do not have to be removed from the precursor film, but it is adequate if most of them are removed. For example, after the precursor film is heat-dried at 150° C. for 10 minutes, the precursor is heated at 450° C. for 10 minutes for heat-decomposing organic matter. As a result, an intermediate layer is formed. To produce dielectric layer 4 of a desired thickness, a process including forming a precursor film, heat-drying the precursor film, and heat-decomposing the precursor is repeated more than once for laminating multiple intermediate layers.

As a result that the intermediate layer is heat-annealed for crystallization, dielectric layer 4 made of (1−x)PMN-xPT can be produced. When the intermediate layer is heat-annealed, the intermediate layer is rapidly heated in a heating furnace for instance. It is preferable that the heating temperature for heat annealing falls in the range of 500° C. or higher and below 750° C. At 750° C. or higher, Pb contained in the precursor film evaporates to cause a shortage of Pb in dielectric layer 4, thereby degrading the crystallinity. When the intermediate layer is heat-annealed, it is rapidly heated at a temperature raising speed of 200° C./min to 650° C., for example. Subsequently, the intermediate layer is heated at 650° C. for 5 minutes. The heating furnace is preferably a rapid thermal annealing furnace; however, it may be an electric furnace or a laser annealing apparatus.

When dielectric layer 4 is formed, a process including forming a precursor film, heat-drying the precursor film, and heat-decomposing and heat-annealing the precursor may be repeated more than once for laminating multiple films made of (1−x)PMN-xPT, thereby forming dielectric layer 4 of a desired thickness.

If dielectric layer 4 is produced by the chemical solution deposition as described above, the (100) plane of (1−x)PMN-xPT in dielectric layer 4 becomes preferentially oriented along interface 6 more easily. This is supposedly because (1−x)PMN-xPT epitaxially grows easily. Further, if dielectric layer 4 is produced by the chemical solution deposition, dielectric layer 4 containing columnar crystals is easily produced.

When dielectric layer 4 containing (1−x)PMN-xPT and a metal oxide other than (1−x)PMN-xPT is produced as well, if dielectric layer 4 is produced by chemical solution deposition using a precursor solution containing a precursor of (1−x)PMN-xPT and a precursor of a metal oxide other than (1−x)PMN-xPT, the (100) plane of (1−x)PMN-xPT becomes preferentially oriented along interface 6 more easily.

For producing dielectric layer 4 by chemical solution deposition, a vacuum process required in vapor deposition such as sputtering is not needed. This allows dielectric layer 4 to be produced easily as well as at low costs.

Subsequently, second electrode layer 5 is formed on dielectric layer 4. For example, second electrode layer 5 made of gold with a thickness of 0.2 μm is formed by vapor deposition. After the above procedures, a dielectric element is completed.

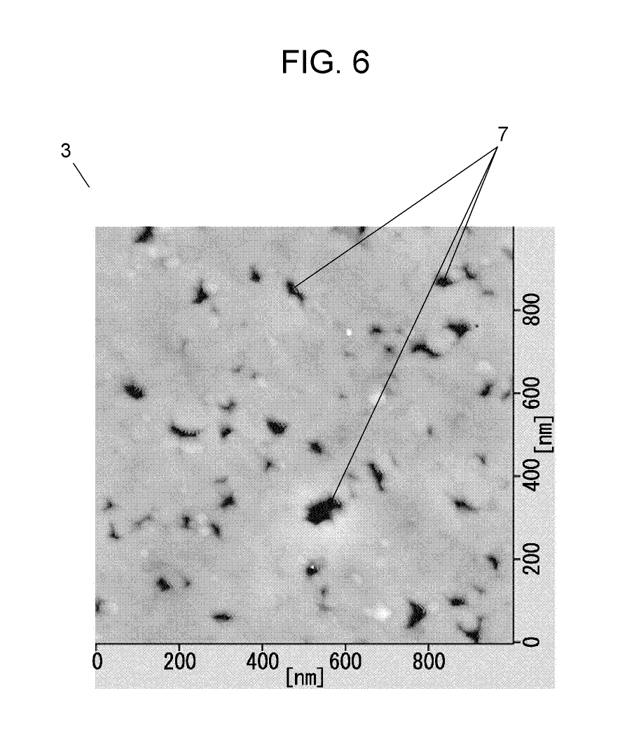

FIG. 6 shows the appearance of pores 7 in first electrode layer 3 made of LNO in a dielectric element produced by the above-described method. FIG. 6 is an observed image by an interatomic force microscope of a cross section of first electrode layer 3. As shown in FIG. 6, pores 7 with diameters of several tens of nanometers are spotted in first electrode layer 3.

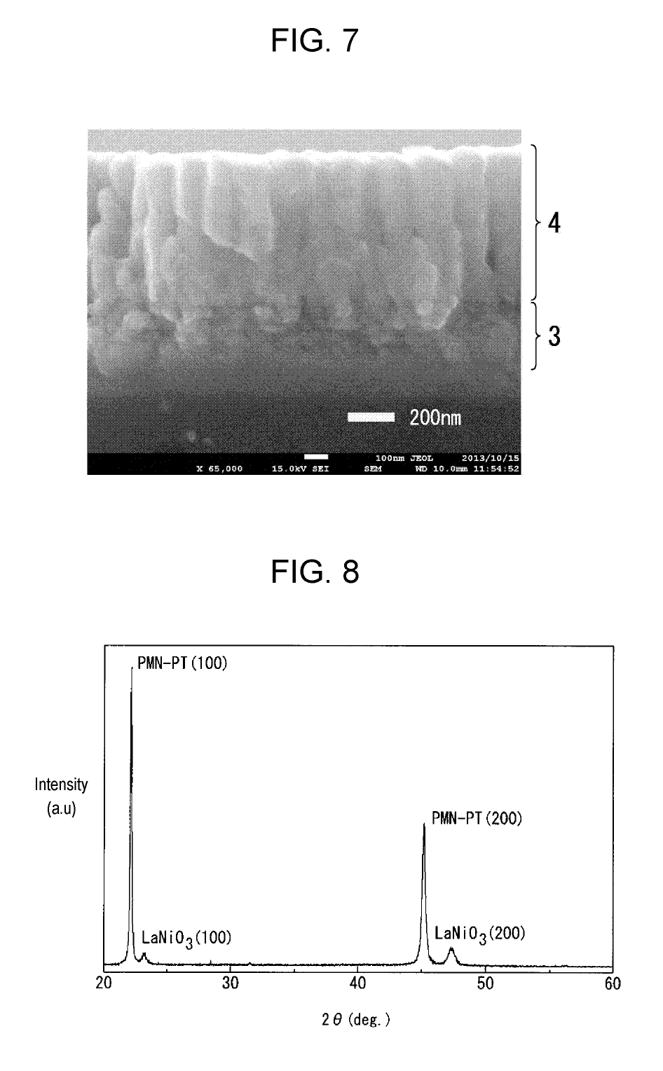

FIG. 7 is an observed image by a scanning electron microscope of a cross section of the dielectric element produced by the above-described method. This dielectric element has first electrode layer 3 made of LNO and dielectric layer 4 made of (1−x)PMN-xPT (where x=0.3). As shown in FIG. 7, dielectric layer 4 contains columnar crystals.

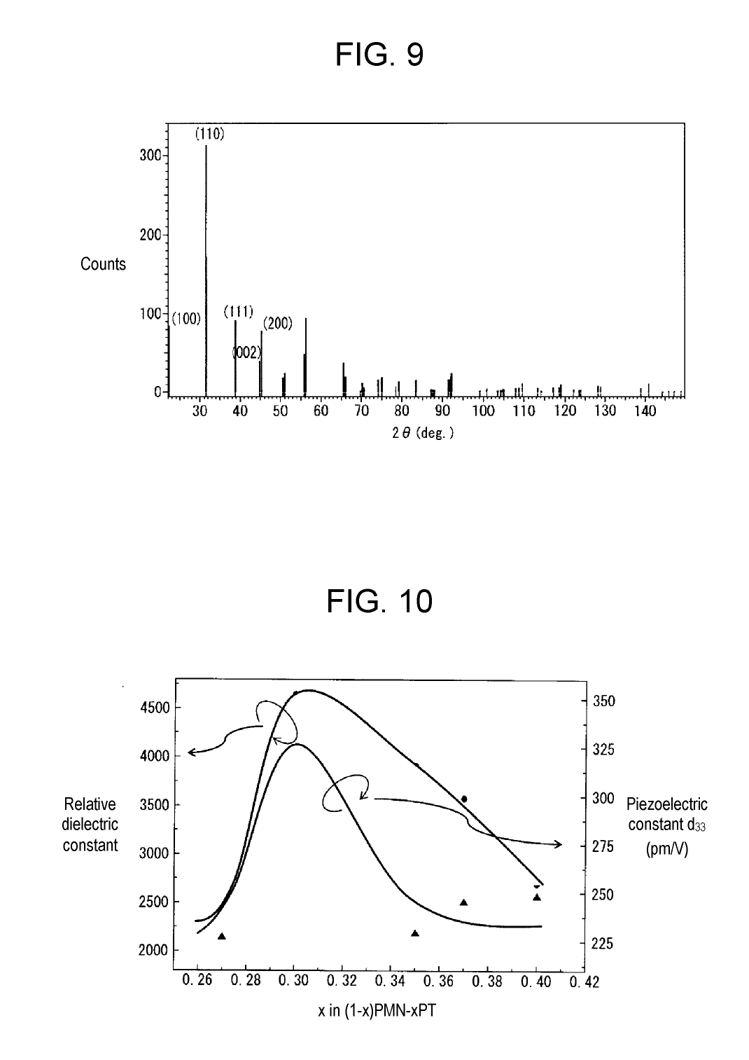

FIG. 8 shows results of evaluating the crystallinity of dielectric layer 4 made of (1−x)PMN-xPT in a dielectric element produced by the above-described method. FIG. 8 shows an X-ray diffraction strength curve obtained by X-ray diffraction measurement of dielectric layer 4 made of (1−x)PMN-xPT (where x=0.3) formed on first electrode layer 3 made of LNO, using Cu-Kα rays. Here, θ is an angle formed between X rays and interface 6. For comparison, FIG. 9 shows a theoretically led X-ray diffraction strength of (1−x)PMN-xPT with an MPB composition in which crystal planes are randomly oriented.

Comparison is made between FIG. 8 and FIG. 9. In FIG. 9, peaks assigned to the (100) plane of (1−x)PMN-xPT and the (200) plane parallel to the (100) plane are found, as well as other peaks naturally. In FIG. 8, on the other hand, peaks assigned to the (100) plane of (1−x)PMN-xPT and the (200) plane in the X-ray diffraction strength curve are found, but no peaks assigned to the other planes are found.

Hence, almost all the (100) planes of (1−x)PMN-xPT are oriented along interface 6 between first electrode layer 3 and dielectric layer 4, and thus the degree of orientation of (1−x)PMN-xPT can be evaluated as being in the range from 0.95 to 1. The perovskite growth rate of (1−x)PMN-xPT in dielectric layer 4 can be evaluated as 100%. Similarly, almost all the (100) planes of LNO are oriented along interface 6 between first electrode layer 3 and dielectric layer 4, and thus the degree of orientation of LNO can be evaluated as being in the range from 0.95 to 1. The perovskite growth rate of LNO can be evaluated as 100%.

FIG. 10 shows results of evaluating the relative dielectric constant and the piezoelectric constant d₃₃ of dielectric layer 4 made of (1−x)PMN-xPT in a dielectric element produced by the above-described method. Note that FIG. 10 shows results of measuring the relative dielectric constant and the piezoelectric constant d₃₃ of multiple dielectric layers 4 produced with different values of x.

In a dielectric element produced by the above-described method, the (100) plane of (1−x)PMN-xPT is oriented along interface 6 between first electrode layer 3 and dielectric layer 4. First electrode layer 3 made of LNO interposed between substrate 1 and dielectric layer 4 suppresses restriction of dielectric layer 4 by substrate 1. Thus, as shown in FIG. 10, the relative dielectric constant of dielectric layer 4 is 2,000 or larger and its piezoelectric constant d₃₃ is 225 pm/V or larger in the range of 0.26≦x≦0.40, both of which represent high values.

In the range of 0.28≦x≦0.33, the relative dielectric constant of dielectric layer 4 is 3,000 or larger and its piezoelectric constant d₃₃ is 270 pm/V or larger, both which represent greatly high values. Especially, when x in 0.3, the relative dielectric constant of dielectric layer 4 is 4,500 or larger and its piezoelectric constant d₃₃ is 320 pm/V or larger, both which represent further greatly high values. Accordingly, the MPB composition of (1−x)PMN-xPT in dielectric layer 4 supposedly shifts closer to the PMN-rich side than a regular composition where x is approximately 0.35.

Note that evaluation is made of a compressive stress in the central part of dielectric layer 4 made of (1−x)PMN-xPT (x=0.3) in a dielectric element produce by the above-described method. A compressive stress can be derived by sin²Ψ method that utilizes X-ray diffraction measurement. Consequently, the compressive stress is as high as 760 MPa.

This high compressive stress is supposed to result from the difference between the thermal expansion coefficient of first electrode layer 3 made of LNO and that of dielectric layer 4 made of (1−x)PMN-xPT. The thermal expansion coefficient of (1−x)PMN-xPT in bulk is approximately 6.3 ppm/K, while that of LNO in bulk is as high as 12.9 ppm/K. For this reason, when dielectric layer 4 made of (1−x)PMN-xPT is formed on first electrode layer 3 made of LNO by a process including heat annealing, first electrode layer 3 contracts to a larger extent than dielectric layer 4 when the temperature of first electrode layer 3 and dielectric layer 4 is lowered after heat annealing. Accordingly, a compressive stress along interface 6 between first electrode layer 3 and dielectric layer 4 is supposed to occur in dielectric layer 4.

From the results of evaluating a compressive stress in dielectric layer 4, a compressive stress occurring in (1−x)PMN-xPT in dielectric layer 4 is supposed to cause the MPB composition of (1−x)PMN-xPT to shift closer to the PMN-rich side than usual. Consequently, the relative dielectric constant and the piezoelectric constant d₃₃ of (1−x)PMN-xPT supposedly represent greatly high values in the range of 0.28≦x≦0.33.

Note that the thermal expansion coefficient of substrate 1 made of silicon is smaller than that of dielectric layer 4 made of (1−x)PMN-xPT. Hence, substrate 1 contracts to a smaller extent than dielectric layer 4 when the temperature of substrate 1 and dielectric layer 4 is lowered after heat annealing. In this embodiment, however, if first electrode layer 3 especially contains pores 7, the difference between the shrinkage of substrate 1 and that of dielectric layer 4 has a slight effect, which hardly exerts a tensile stress on dielectric layer 4. This is supposedly because pores 7 contained in first electrode layer 3 provide a certain degree of flexibility to first electrode layer 3, which moderates a stress resulting from the difference between the shrinkage of substrate 1 and that of dielectric layer 4.

In the above-described method, substrate 1 is made of silicon; however, it is also preferable that substrate 1 is formed of a material with a high fracture toughness such as stainless steel. A material with a high fracture toughness is particularly suitable when the dielectric element is applied to a device that repeatedly vibrates, such as a sensor and actuator. In those cases, the reliability of the dielectric element can be enhanced. Further, even if a defect such as minute cracks occurs in an part composing a dielectric element during its production process, the risk of producing cleavage cracks starting from the defect is dramatically reduced as compared to substrate 1 made of silicon. Therefore, the production yield of dielectric elements is increased. Further, stainless steel is less expensive and more easily available than silicon, which reduces the production cost of substrate 1.

As described above, a dielectric element according to the disclosure includes a dielectric layer containing (1−x)PMN-xPT and having a large dielectric constant and a large piezoelectric constant. Accordingly, the dielectric element is useful for devices such as a capacitor, a dielectric bolometer type infrared sensor, a piezoelectric actuator, and a ultrasonic motor.

What is claimed is:

1. A dielectric element comprising:
a substrate;
a first electrode layer disposed on the substrate;
a dielectric layer disposed on the first electrode layer; and
a second electrode layer disposed on the dielectric layer,
wherein the first electrode layer contains lanthanum nickelate,
the dielectric layer contains lead magnesate niobate-titanate represented by (1−x)Pb(Mg_{1/3}Nb_{2/3})O₃-xPbTiO₃, x satisfying 0.28≦x≦0.33, and
a (100) plane of the lead magnesate niobate-titanate is preferentially oriented along an interface between the first electrode layer and the dielectric layer.

2. The dielectric element according to claim 1, wherein the dielectric layer has a columnar crystal structure.

3. The dielectric element according to claim 1, wherein the dielectric layer has a compressive stress along the interface.

4. The dielectric element according to claim 3, wherein the dielectric layer has a thermal expansion coefficient smaller than that of the first electrode layer.

5. The dielectric element according to claim 1, wherein the first electrode layer contains a plurality of pores therein.

6. The dielectric element according to claim 5, wherein the first electrode layer has a first layer containing the plurality of pores therein and a second layer not containing a pore therein, the second layer being disposed between the first layer and the dielectric layer.

7. The dielectric element according to claim 6, wherein a diameter of the plurality of pores becomes smaller from the substrate toward the dielectric layer.

8. The dielectric element according to claim 5, wherein a diameter of the plurality of pores becomes smaller from the substrate toward the dielectric layer.

9. The dielectric element according to claim 1, further comprising a diffusion prevention layer between the substrate and the first electrode layer.

10. The dielectric element according to claim 1, wherein a (100) plane of the lanthanum nickelate is preferentially oriented along the interface.

11. A piezoelectric element comprising:
a substrate;
a first electrode layer disposed on the substrate;
a dielectric layer disposed on the first electrode layer; and
a second electrode layer disposed on the dielectric layer,
wherein the first electrode layer contains lanthanum nickelate,
the dielectric layer contains lead magnesate niobate-titanate represented by (1−x)Pb(Mg_{1/3}Nb_{2/3})O₃-xPbTiO₃, x satisfying 0.28≦x≦0.33, and
a (100) plane of the lead magnesate niobate-titanate is preferentially oriented along an interface between the first electrode layer and the dielectric layer.
